(19) United States
(12) Patent Application Publication
(10) Pub. No.: US 2010/0151677 A1
(43) Pub. Date: Jun. 17, 2010

(54) ETCH METHOD IN THE MANUFACTURE OF A SEMICONDUCTOR DEVICE

(75) Inventors: Greg Braeckelmann, Grenoble (FR); Susana Bonnetier, Vaulnaveys Le Haut (FR)

Correspondence Address: LARSON NEWMAN & ABEL, LLP, 5914 WEST COURTYARD DRIVE, SUITE 200, AUSTIN, TX, 78730, US

(73) Assignee: Freescale Semiconductor, Inc., Austin, TX (US)

(21) Appl. No.: 12/594,374

(22) PCT Filed: Apr. 12, 2007
(86) PCT No.: PCT/IB07/52677

§ 371 Date: Oct. 2, 2009

(51) Int. Cl. H01L 21/768

(52) U.S. Cl. 438/664; 257/E21.585

(57) ABSTRACT

The present invention provides a method for forming a transistor on a silicon substrate, the method comprising: providing a substrate comprising: a gate electrode with a liner comprising silicon and oxygen, and with a sidewall spacer, and source and/or drain region(s) in the substrate adjacent to the gate electrode, a layer at least 5 nm thick comprising silicon dioxide covering at least the source and/or drain regions; etching the layer comprising silicon and oxygen from at least the source and/or drain regions; and forming contacts for the source and/or drain region(s), characterized in that the layer comprising silicon and oxygen is etched from the substrate by steps comprising: forming an etchant from a plasma formed from a mixture comprising nitrogen trifluoride and ammonia; exposing the substrate to the etchant; and annealing the substrate.

### FIELD OF THE INVENTION

The present invention relates to a method of etching in the manufacture of a semiconductor device. More particularly, the present invention relates to a method of etching in the formation of a transistor on a substrate.

### BACKGROUND TO THE INVENTION

A conventional field effect transistor is illustrated in FIG. 1. Source/drain extensions (106 and 110) and source/drain regions (104 and 108) lie in a substrate (100) adjacent to a gate electrode (102). The source and drain extensions are sometimes called lightly-doped sections, and the source and drain regions are sometimes called heavily-doped regions. The source and drain regions have contacts or terminals (112 and 114) to connect the source and drain to an electronic circuit. The gate electrode also has sidewall liners (116) on both of its sidewalls, and sidewall spacers (118) adjoining the sidewall liners (116). The sidewall liners typically comprise silicon dioxide, while the sidewall spacers typically comprise silicon nitride.

FIGS. 2 and 3 illustrate a method of manufacturing a conventional field effect transistor. In FIG. 2A, a gate electrode (102) with opposing sidewalls is provided. Then, source/drain extensions (106 and 110) are produced by conventional ion implantation, as shown in FIG. 2B. Next, liners (116) are formed on the opposing sidewalls of the gate electrode, followed by sidewall spacers (118) on the sidewall liners. This is shown in FIG. 2C. After the formation of the sidewall spacers, the source/drain regions (104 and 108) are formed by a second (conventional) ion implantation, as shown in FIG. 2D.

After the second ion implantation, the substrate is annealed. A similar annealing step may also be carried out after the first ion implantation step. The annealing activates the dopants deposited during the ion implantation. Annealing may be carried out, for example, between 800 and 1300° C. (e.g. at 1060° C.). One specific method of annealing involves a ‘spike’ anneal in which a substrate is heated to a maximum temperature and immediately cooled down (i.e. the substrate effectively spends less than around 1 second being heated at the maximum temperature). The rate of heating and cooling when carrying out a spike annealing process may be from 50 to 250° C./s.

Between the second ion implantation step and the formation of the source/drain contacts, a thin oxide layer (a ‘native’ oxide layer) of around 0.5 to 2 nanometers (nm) thickness is generally formed at the surface of the substrate. This is formed spontaneously when the surface is exposed to an atmosphere containing even small amounts of oxygen at room temperature. Therefore, a native oxide layer may form, for example, when the silicon substrate is transferred from one tool to another.

The native oxide layer is usually removed before the formation of the source/drain contacts because its presence reduces the efficacy and reproducibility of the contact-forming process. The removal of the native oxide is typically carried out by rinsing the substrate with a solution of HF. Alternatively, it may be removed by treatment with a plasma or reactive gas.

In addition to this thin (native) oxide layer spontaneously growing on the substrate, a thick oxide layer has sometimes been deposited on/formed in the substrate. This oxide layer is much thicker than the native oxide layer—it is typically more than 5 nm (50 Ångstroms) in thickness. This ‘thick’ oxide layer is used to protect the surface of the substrate, both from further oxidation and contamination. It may also be used to protect certain parts of the surface from reaction later on in the manufacturing process and is sometimes called a ‘silicon protect’ layer.

The use of a protective layer is described in US2002/0158291, in which a protective layer is used to protect a polysilicon resistor on a surface; in US2002/0123192, a protective layer is used to protect a sensitive memory FET; and in U.S. Pat. No. 6,025,267, a protective layer is used to protect an entire portion of a surface. In these examples, a protective layer is patterned with an etch-resistant mask and then the unpatterned areas of the protective layer are selectively etched. The photoresist is then sometimes removed, and the source and drain contacts are formed.

The source and drain contacts illustrated in FIG. 1 are formed in the body of the substrate (100) rather than on its surface. Contacts of this type are typically made from a metal silicide using a self-aligned silicide process (also known as a salicide process). The contacts are made by depositing a layer of metal or metal alloy (120) on top of a silicon substrate to produce the substrate shown in FIG. 2E, and then heating the substrate. This causes an alloying reaction between the metal (or metal alloy) and the silicon to form the metal silicide contact, as shown in FIG. 2F.

In the past, favoured metals used for forming the source and drain contacts (108 and 110) have included titanium and cobalt. Platinum and tungsten have also been used. For the alloying reaction of these materials, the substrate may typically be heated to a temperature from 600 to 800° C. for 30 minutes in a nitrogen atmosphere. Alternatively, in a process called ‘Rapid Thermal Anneal’ (RTA), the substrate may be heated to a higher temperature (around 1000° C.) for less time (around 30 seconds).

However, nickel and alloys of nickel are becoming increasingly used to form the source and drain contacts (108 and 110) because of their advantageous properties and processing conditions. For example, nickel silicide can be rapidly formed at a low temperature (below 600° C., sometimes as low as about 200° C.), making it suitable for use in the low temperature manufacture of a semiconductor device. Nickel silicide also has low contact resistance and low resistivity. It can also be reliably formed on small areas of polycrystalline silicon ('poly lines').

One alloy of nickel that is becoming increasingly favoured for use in the salicide process is a nickel/platinum alloy. The alloy may comprise from 1 to 15 at % (atomic percent) of platinum, for example around 5 at %.

During the salicide process, the presence of sidewall liners and spacers ensures that the metal silicide contact that is formed and the gate electrode are spatially and electrically separated. Otherwise, the source and drain contacts would be in close proximity to one another, causing the transistor to short circuit or have a reduced lifespan. In particular, the performance and reliability of a device is dependent on the final position of the silicide with respect to the channel region under the gate electrode. This is effectively determined by the position of the sidewall spacers and liners (116 and 118).

The sidewall liners (116) also serve several other functions. They help to reduce hot carrier effects, caused by hot carrier injection of high energy electrons, thereby increasing the reliability of a device. They may also act as an etch stop layer.

A cross-section of part of a transistor formed by a conventional method (including deposition and removal of a ‘thick’ protective oxide layer) is illustrated by Example 1 and FIG. 4. The image in FIG. 4 was recorded by transmission electron microscopy (TEM). The sidewall liner is made from silicon dioxide. The edge of the sidewall spacer/liner on the left hand side of the Figure has been emphasised by adding a black line. The Figure shows that part of the oxide liner has been removed during the manufacture process, undercutting the sidewall spacer. As explained above, this undercutting reduces the spatial and electronic separation between the source/drain contacts and the gate electrode, and thereby reduces the performance and reliability of the final device.

The inventors have found that this undercutting of the spacer is caused by conventional methods of cleaning and treating the substrate prior to the salicide process. As such, the undercut is partly caused by etch and cleaning steps performed after the formation of the sidewall liners and spacers; it is also partly caused by etch and cleaning steps performed after the formation of the source/drain extensions and regions. However, the inventors have found that the most significant cause of this undercutting is the etch and cleaning steps to remove the protective oxide layer performed just before the salicide process. These etch and cleaning steps are important to remove as much of the protective oxide as possible from the substrate surface just before metal deposition because otherwise the metal silicide is not consistently formed. The inventors have found that etching with conventional techniques such as with HF or HCl remove both the oxide layer and part of the oxide liner at the same time. This is because these etching steps are not selective about the oxide that is etched.

The inventors have also found that the amount of undercutting is partly dependent on the amount of time that a substrate is exposed to an etchant. As a result, undercutting is more significant when removing the protective oxide layer (5 nm or more in thickness) compared to the thinner native oxide layer (less than 2 nm in thickness). This is because a longer etching time is needed to remove the thicker protective oxide layer.

This undercutting is also particularly disadvantageous when a nickel silicide is used as the source/drain contact. This is because nickel silicides and silicides made from alloys of nickel suffer from high rates of diffusion. This means that transistors incorporating nickel silicides are particularly prone to high junction leakage, associated yield loss and low working lifetimes.

In view of at least some of the problems associated with the prior art, the inventors have devised a new method for preparing a semiconductor substrate before forming the source/drain contacts. This method is aimed at addressing some of the problems associated with the undercutting of the sidewall spacer on the gate electrode, in particular when removing the protective oxide layer, thereby reducing the junction leakage of the transistor and decreasing the yield loss.

### SUMMARY OF INVENTION

The present invention provides a method for forming a transistor on a silicon substrate as described in the accompanying claims.

### BRIEF DESCRIPTION OF THE DRAWINGS

The present invention will now be described in relation to some drawings, which are provided by way of example:

FIG. 1 depicts a conventional transistor.

FIG. 2 depicts steps in the conventional manufacture of a transistor.

FIG. 3 is a flow-diagram of steps involved in the conventional manufacture of a transistor.

FIG. 4 is a TEM image of a transistor manufactured by a conventional manufacture process.

FIG. 5A shows a substrate with source/drain regions covered by a silicon dioxide protective layer as provided in the first step of the method of the present invention.

FIG. 6 shows the chemical processes thought to be occurring in the etch step of the method of the present invention.

FIG. 7 is a TEM image of a transistor manufactured by the method of the present invention.

FIG. 8 is a flow-chart depicting one embodiment of the method of the present invention.

FIG. 9 is a TEM image of a transistor as described below.

FIG. 10 is a TEM image of a transistor manufactured according to one embodiment of the method of the present invention.

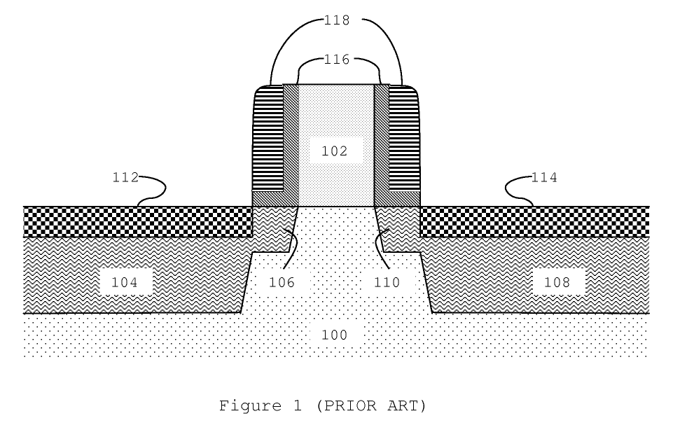

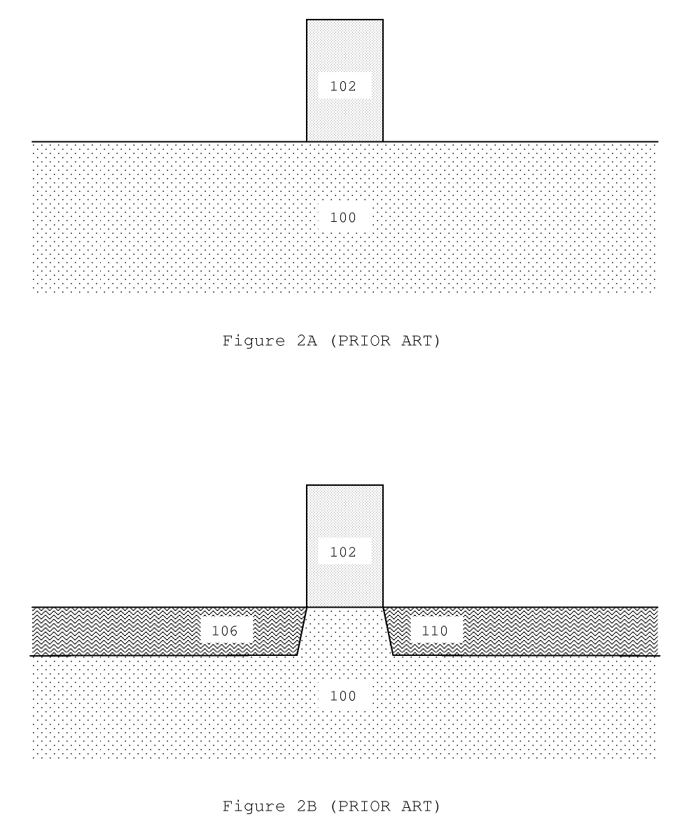

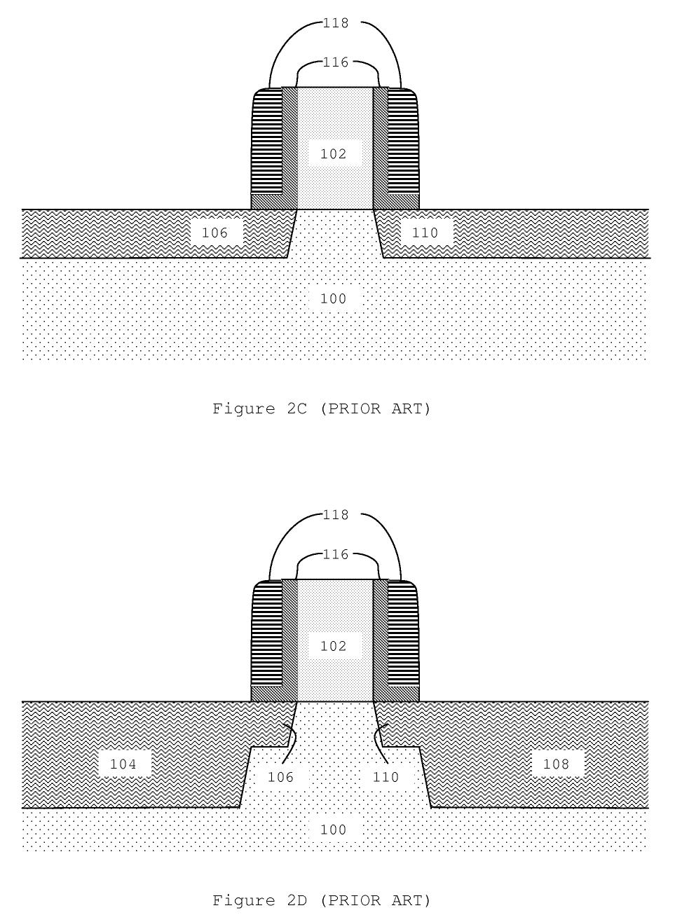

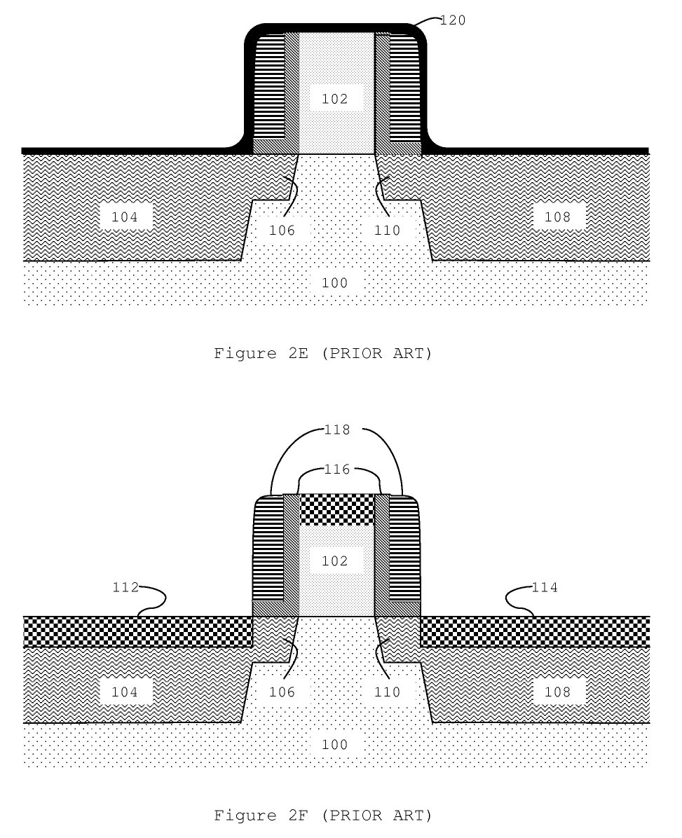

### DETAILED DESCRIPTION OF THE INVENTION

As used herein, a silicon substrate refers to any substrate that comprises silicon. This includes, amongst other substances, different forms of elemental silicon and alloys of silicon. Suitable substrates include poly-crystalline silicon (poly-silicon), SOI (silicon on insulator) and SiGe.

As used herein, a thickness of a layer is measured in the direction perpendicular to the plane of the surface of the immediately underlying layer. For example, the thickness of a blanket layer is measured perpendicular to the plane of layer underlying the blanket layer (e.g. perpendicular to the plane of the silicon substrate). It is measured by taking a cross-section of the substrate by TEM.

As used herein, etching a layer means removing at least part of the layer. This includes removing substantially all of the layer.

The layer comprising silicon and oxygen may be an oxide of silicon. For example, it may be of the form SiOₓ, where x may be about 2 (although it may be more or it may be less). Preferably, it is or comprises silicon dioxide. This layer will sometimes be referred to below as a silicon dioxide layer or a silicon oxide (i.e. an oxide comprising silicon) layer for illustrative purposes. However, embodiments that are described in relation to a silicon oxide or silicon dioxide layer may be equally applied to all layers comprising silicon and oxygen.

The terms ‘gate electrode’, ‘liner’, ‘sidewall spacer’, ‘source region’ and ‘drain region’ are conventional terms in the art.

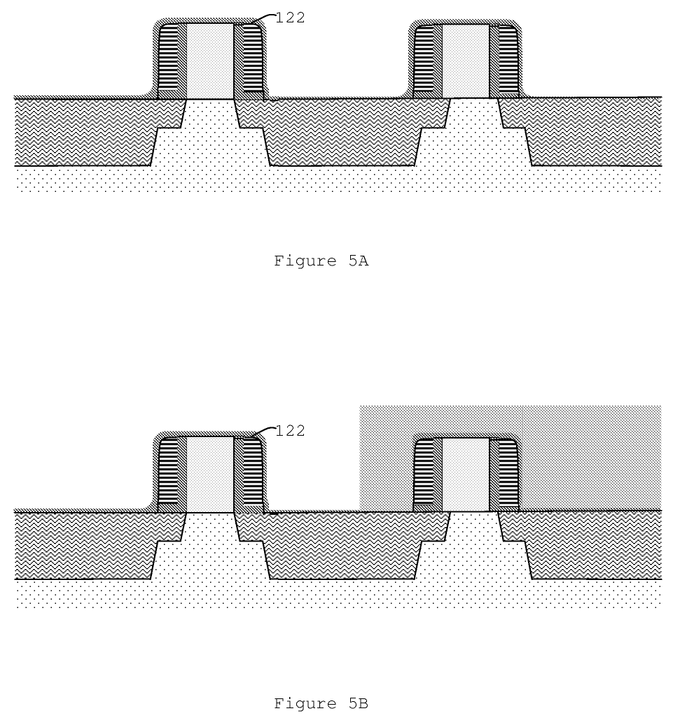

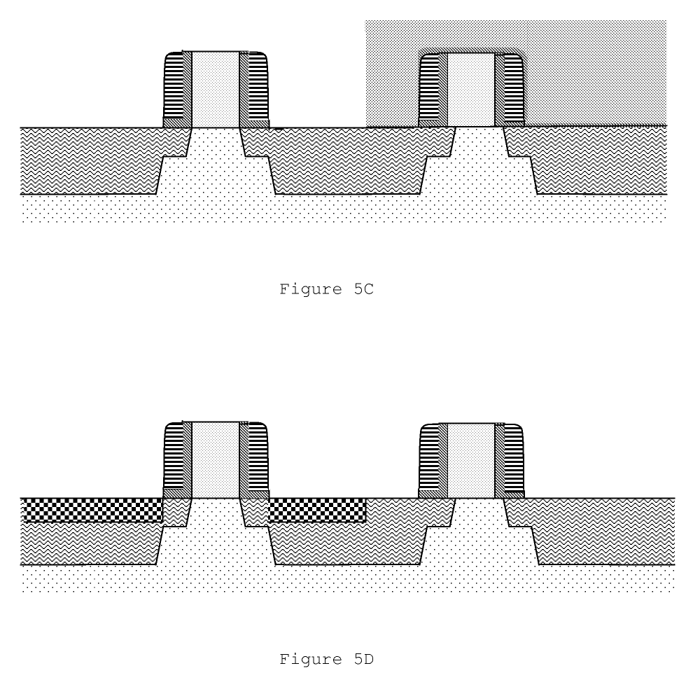

The method of the present invention helps to prevent the undercutting of the sidewall spacers by using a reactive gas to remove a silicon oxide protective layer. Firstly, a substrate with a blanket (protective) layer comprising silicon and oxygen is prepared. The substrate is illustrated in FIG. 5A, with the layer comprising silicon and oxygen illustrated as 122. The blanket layer is deposited by any conventional method of depositing a layer comprising silicon and oxygen. For example, it may be formed by Chemical Vapour Deposition (CVD) using a triethylorthosilicate (TEOS) precursor. The blanket layer is typically on average 5 nm or more in thickness, and typically 300 nm or less on average in thickness. The layer should have at least 5 nm mean thickness because otherwise the layer does not adequately protect the surface from unwanted reaction, oxidation and contamination. If the layer has greater than 300 nm mean thickness, it sometimes disadvantageously increases the length of time required to remove the layer before the start of the salicide process.

The blanket layer comprising silicon and oxygen may be deposited by itself or other layers may be deposited on top of it. If it is deposited by itself, the thickness of the layer may typically be from 100 nm to 300 nm in thickness, for example from 175 to 225 nm, for example about 200 nm. Alternatively, a second layer may be deposited on top of the (first) layer that comprises silicon and oxygen. This layer may comprise silicon and nitrogen, such as a nitride of silicon (e.g. silicon nitride). With this second layer present, the first layer may typically be from 5 to 50 nm in thickness, for example from 15 to 25 nm in thickness, for example about 20 nm. The overlying second layer may typically be from 5 to 50 nm in thickness, for example from 7.5 to 12.5 nm in thickness, for example about 10 nm.

Once the protective layer is formed, it is possible to handle the substrate freely in the laboratory atmosphere without having to take special precautions against the oxidation of the surface.

When the substrate is ready to be subjected to the salicide process, the protective layer is removed from the substrate. It is removed by the following etch process:
(i) firstly, an etchant is formed in a remote plasma formed from a gas mixture comprising nitrogen trifluoride and ammonia;
(ii) the substrate is then exposed to the etchant; and
(iii) then the substrate is annealed.

Effectively, the substrate is being treated in this process with a remote plasma (a plasma that has been formed away from the substrate). The plasma is used to generate reactive gaseous species which are then brought in contact with the substrate.

The chemical processes thought to be occurring during this reactive gas etching are illustrated in FIG. 6. FIG. 6 illustrates the process in relation to the removal of silicon dioxide, although similar processes are thought to occur with the removal of other layers comprising silicon and oxygen. This Figure is for the purposes of illustration and it should not be considered to limit the scope of the invention. In FIG. 6, firstly a plasma is formed remotely from a gas mixture comprising ammonia and nitrogen trifluoride. This results in the formation of a neutral reactive species, NH₄F. This neutral species is then allowed to come into contact with the substrate, and reacts with the silicon dioxide on the surface to form water and a thin film comprising (NH₄)₂SiF₆. The water is removed under the process conditions because the system is under vacuum. Then, in the subsequent step, the substrate is annealed. This annealing allows the thin film to be desorbed from the surface as NH₃ and SiF₄. Typically, the temperature of the reaction chamber will be from 40 to 100° C. (for example, around 60° C.). The pedestal holding the wafer may be independently heated to a temperature from 25 to 50° C. (for example, around 35° C.).

In this reaction sequence, the substrate is not directly exposed to a plasma because exposure to plasma can lead to decrease in the reliability of the final device.

In step (iii), the substrate is annealed by exposing it to a heat source. Typically, the substrate will be exposed to the heat source for 20 seconds or greater, for example 30 seconds or greater (i.e. a soak anneal may be used). The temperature to which the wafer is heated may be between 50 and 200° C., for example between 75 and 150° C. which facilitates the desorption of the thin film. Although the desorption of the film occurs easily under vacuum (e.g. at a pressure of 0.01 atmospheres or less), H₂ gas may also be heated to the above temperatures and pumped into the processing chamber by flowing it through a hot showerhead.

This increases the heat transfer from the showerhead to the wafer.

As described in relation to the prior art, the blanket silicon oxide layer (or, if present, the layer comprising silicon and nitrogen) may be patterned with a lithograph mask (photoresist) in a conventional manner before being exposed to the etch process of the present invention. This may be carried out so that, for example, some gate electrodes and/or source/drain areas can be protected during the subsequent salicide process to keep them free from metal silicide. These protected areas may form circuit elements such as high resistance lines. Alternatively, this technique may be used as a tool to identify potential problems with the salicide process. In this case, when a problem with the manufacturing process is identified, silicided and unsilicided structures may be compared to determine whether a problem is caused during the patterning steps or during the silicidation process.

An example of this patterning technique is shown in FIGS. 5B and 5C. In FIG. 5B, a lithographic mask has been selectively formed over the surface of the silicon oxide blanket layer. Then, when the plasma treatment is performed, only the exposed part of the layer comprising silicon and oxygen is etched. Metal (or metal alloy) is then deposited and the substrate is annealed. The mask may be removed either before or after the salicide process. The remaining silicon oxide protective layer may finally be removed, usually using conventional techniques. Alternatively, the etch method of the present invention may be used in some circumstances.

An example of a resulting structure is shown in FIG. 5D. It can be seen from this Figure that some of the gate electrodes on a surface can be selectively subjected to the salicide process.

If other layers have been deposited on top of the silicon oxide ‘protective’ layer, these may be removed by conventional means. For example, if a layer comprising silicon and nitrogen (e.g. silicon nitride) has been deposited on top of the silicon oxide layer, this may be removed by conventional reactive ion etching, for example with a fluorine- or chlorine-containing etchant.

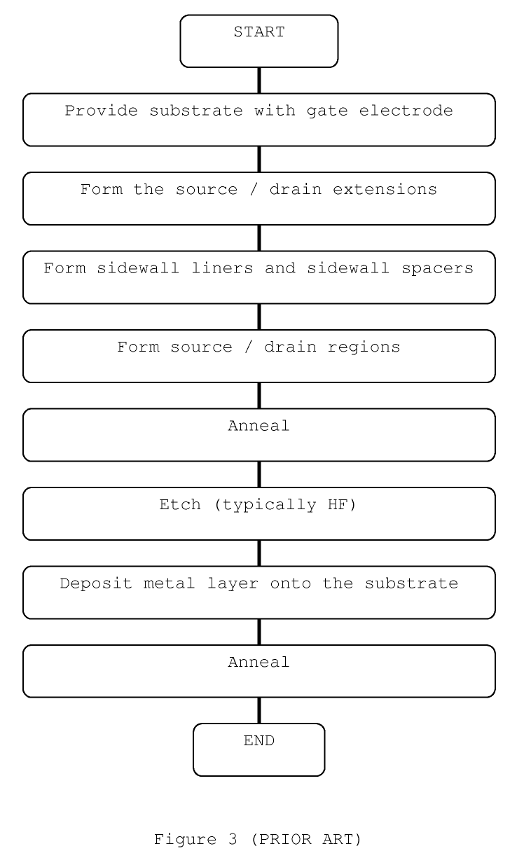

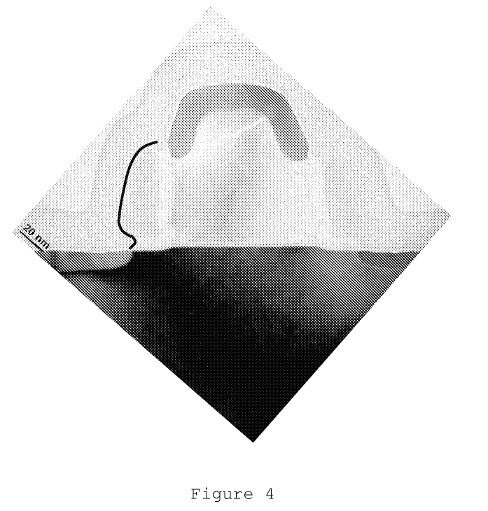

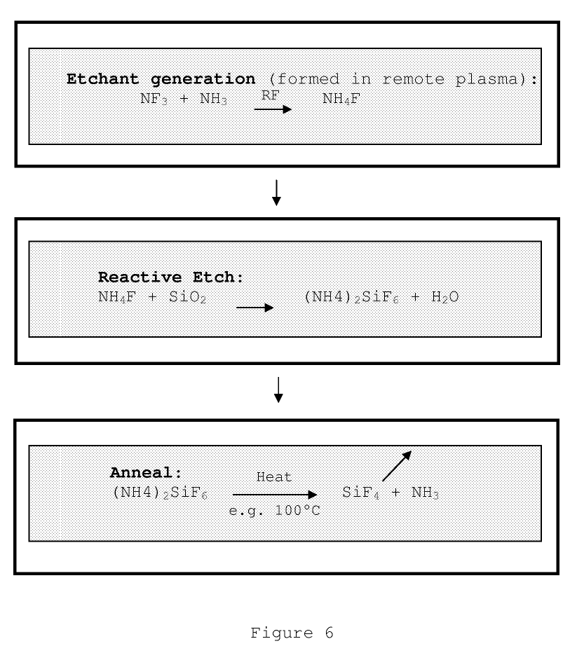

A substrate prepared using the process of the present invention is illustrated by Example 2 and FIG. 7. The profile of the sidewall liner/spacer is emphasised by the black line. It is evident that there has been no undercutting of the sidewall spacer using the method of the present invention. This should be compared with the profile previously presented in FIG. 4 for a substrate prepared by conventional methods.

It is apparent from this example that, in one aspect, the present invention provides a method for preventing undercutting of a sidewall spacer in the etching of a layer comprising silicon and oxygen in the manufacture of a semiconductor device. As noted previously, the extent of undercutting in methods of the prior art is dependent on the time exposed to the etching conditions and therefore the thickness of the layer comprising silicon and oxygen. As a result, the method of the present invention may be particularly used to prevent undercutting of a sidewall spacer in the etching of a layer comprising silicon and oxygen of 5 nm or greater in thickness.

When undercutting occurs, part of the sidewall liner adjoining the surface of the silicon substrate is removed. As a result, when the salicide steps are carried out, there is uncertainty about the position of silicide formation relative to the gate electrode because of the uncertainty of the position of the sidewall liner after etching. This results in a loss of control of the distance that silicide formation occurs from the gate electrode. However, because the method of the present invention helps to prevent undercutting, the position of the sidewall liner relative to the gate electrode is approximately the same before and after etching. This means that the position of silicide formation can be controlled to occur at any distance from the gate electrode by the method of the present invention through control of the profile of the sidewall liner.

In the first step of the method of the present invention, the ammonia flow rate is typically from 50 to 150 sccm (standard cubic centimetres per minute), for example from 70 to 100 sccm. The NF₃ flow rate is typically from 2 to 40 sccm, for example from 5 to 15 sccm. Accordingly, the ratio of NH₃ to NF₃ is typically from 20:1 to 5:1, for example about 10:1. The plasma is typically generated at an RF power of 20 to 40 Watts (for example about 30 Watts) for a plasma chamber having a volume of 740 cc. The power density in the plasma chamber may be between 10 and 100 mW/cc, for example between 25 and 60 mW/cc, for example around 40 mW/cc. The etch rate of the substrate (being defined as the time that the wafer is exposed to the reactive gas) is typically from 0.2 to 0.5 nm per second.

A carrier/dilution gas may also be added to the gas mixture from which the plasma is generated. This gas may be, for example, a noble gas, such as helium or argon.

In the second step, the substrate may be heated by a hot showerhead. The showerhead may be at a temperature from 150 to 250° C., for example about 180° C. The substrate is heated to a temperature of typically above 80° C. as a result, for example about 100° C. To improve the heating of the wafer and to facilitate the removal of exhaust gasses from the system, hydrogen and/or argon may be flowed over the substrate (at a rate of 800 to 1200 sccm).

The etch process described above can be used either by itself without any other etching process, or in combination with a conventional etching process, for example with a conventional HF etch. In this case, the amount of time that the substrate is exposed to the HF etching solution is reduced compared to a conventional etch.

A conventional HF etch involves exposing the substrate to an aqueous HF solution. This solution may simply contain HF and water or it may contain other components such as surfactants or anti-oxidants. The solution may contain from 0.01 to 2 wt % of HF, for example from 0.1 to 1 wt %, for example about 0.5 wt %. These limits are set to enable the controlled and reproducible rate of etching of the substrate.

A typical HF etching solution is made by diluting a 49 wt % solution of HF in water with ultra pure water in a ratio of 1:200, the ratio given in terms of volume (i.e. 1 ml of 49 wt % aqueous HF solution is diluted with 200 ml of ultra pure water). The substrate is then exposed to this solution at around room temperature (for example about 20° C.). This typically etches around 1.5 nm of the substrate each minute.

The inventors have found that it is sometimes beneficial to carry out a conventional HF etch before the etch treatment of the present invention. This is because the inventors have found that reactive gas etching sometimes fails to completely remove a thick layer comprising silicon and oxygen at the surface (e.g. 10 nm or above in thickness). However, undercutting of the sidewall spacer is still reduced because the amount of time exposed to the HF solution etch is reduced compared to a conventional process.

Once the etching has been performed, a conventional salicide process is performed to form the source/drain contacts. This is typically carried out in the same cluster tool as the previous NH₃/NF₃ etch process. The wafer may be transferred under ultra-high vacuum (i.e. at less than 10⁻⁸ Torr) from the etch chamber to the deposition chamber. This reduces the chance of any unwanted oxide being formed on the surface of the freshly-exposed substrate.

The salicide process typically involves depositing a metal or metal alloy layer from 5 to 15 nm in thickness, for example about 10 nm in thickness. The metal may be, for example, nickel, or, for example, a nickel/5 at % platinum alloy. The metal (or metal alloy) layer may be deposited by a conventional method, such as sputtering (PVD) or CVD. A capping layer may optionally then be deposited on top of the metal or alloy layer. This capping layer protects the substrate during the subsequent annealing process. The capping layer may comprise, for example, titanium, titanium nitride, tantalum or tantalum nitride. It may be deposited to have a thickness from 5 to 20 nm, for example about 10 nm. Finally, the system undergoes annealing to form the metal silicide. Annealing may be carried out, for example, by rapid thermal annealing, at a temperature range from 200 to 400° C., for a time between 0 (i.e. for spike annealing) and 300 seconds. For example, the substrate may be heated to about 300° C. for about 30 seconds.

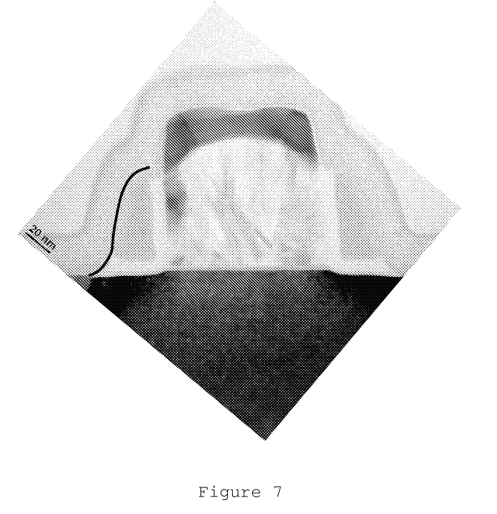

One embodiment of the overall process from start to finish, including the formation of the source/drain regions prior to the deposition of the blanket protective layer, is shown in the flow chart in FIG. 8.

The inventors have found that the method of the present invention helps to prevent undercutting of the oxide spacer when etching the protective insulator layer. However, the inventors have found that sometimes the etch method does not remove absolutely all of the protective layer comprising an oxide of silicon. The inventors have found that this is especially a problem in crowded/pinched active areas. This is a problem because the oxide comprising silicon that remains prevents silicidation, degrading the performance of the final device.

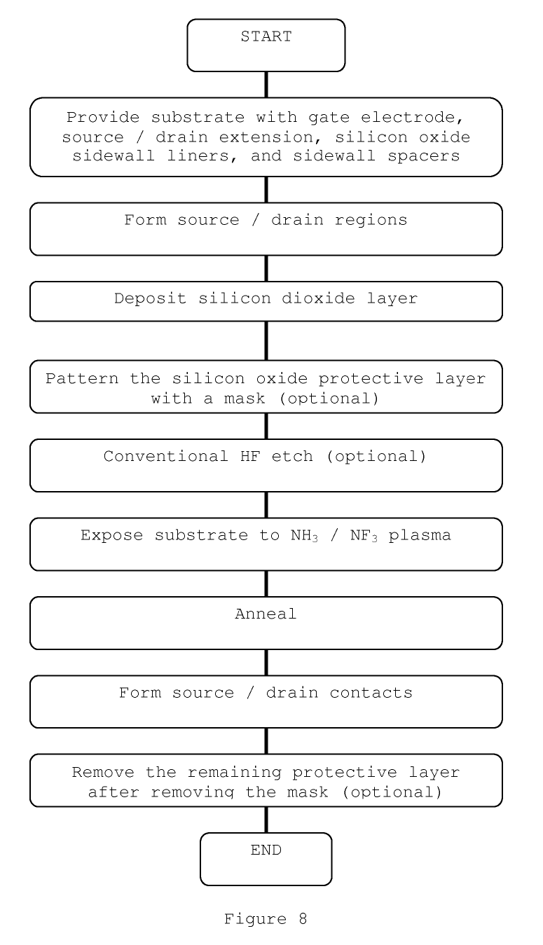

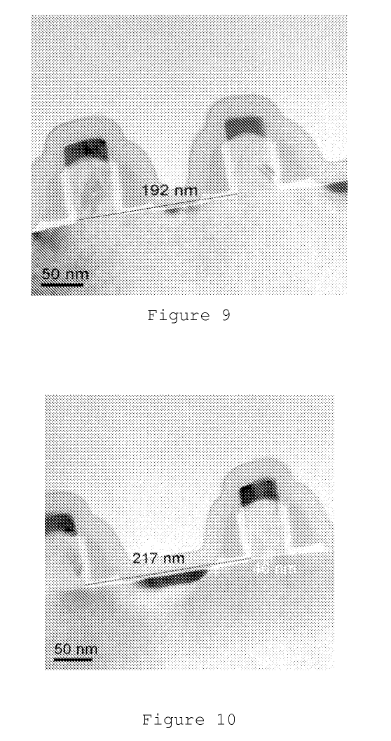

An example of a substrate that has not been fully etched is shown in FIG. 9. Very little nickel silicide (which is seen as black) has been formed in the constricted area between the two electrode stacks. As illustrated in the Figure, the two electrodes are only approximately 190 nm apart. This has been identified by the inventors to be caused by the incomplete removal of the silicon dioxide in the etching step prior to silicidation.

One approach to ensuring that the oxide protective layer is completely removed is to ‘overetch’ the substrate. As noted above, etching rates may be about 0.5 nm per second. Therefore, to etch a 5 nm thick protective layer, etching would normally be carried out for about 10 seconds. However, in order to ensure that oxide is removed from the pinched active areas, etching time can be typically doubled or tripled, so in this example it may be as much as 30 seconds.

Another approach (described above) is to carry out a reduced conventional HF etch before the etch method of the present invention.

However, the inventors have found that repeating the etch process more than once (i.e. more than one cycle of exposing the substrate to the reactive gas formed from the plasma and then annealing) can advantageously facilitate the removal of oxide from low-accessible areas. For example, repeating the above exemplified process twice would lead to an etch time of 20 seconds or less. Therefore, this is an industrially beneficial process because it allows for the more efficient removal of the protective oxide.

An example of a substrate having a low-accessible or pinched area is shown in FIG. 10. The electrode stacks are only 217 nm apart, but nickel silicide has clearly been successfully formed in between the two stacks. This is thought to be achieved when the substrate is subject to two etching cycles (i.e. exposing to the reactive gas; annealing; exposing to the reactive gas; annealing). Therefore, the silicon dioxide protective layer in the pinched active (i.e. crowded) area is thus removed prior to silicidation.

The etch process may be repeated any number of times. However, for the sake of practicality, it will normally be repeated once, or possibly twice.

The present invention also provides the use of an etchant formed from a plasma formed from a mixture comprising NF₃ and NH₃ in the prevention of undercutting of a sidewall spacer in etching of a layer comprising silicon and oxygen in the manufacture of a transistor. This layer may be at least 5 nm in thickness. The various embodiments associated with this use are the same as those described above in relation to the method of the present invention.

The present invention also provides a semiconductor substrate (in particular a transistor or a gate electrode) formed by the method described above. The various embodiments associated with this product are the same as those described above in relation to the method of the present invention.

The present invention will now be illustrated by a number of examples. These examples have been discussed previously.

### EXAMPLES

In all the following examples, a 20 nm silicon oxide layer had been deposited on the surface of the substrate under the following conditions:
Wafer Chuck Temperature: 400° C.
Chamber Pressure: 5 Torr
TEOS flow rate: 1 slm
He flow rate: 9 slm (standard liters per minute)
O2 flow rate: 8 slm
RF Power: 215 W
Depostion Time: 10 s

A 20 nm nitride layer was then deposited on top of the silicon oxide layer under the following conditions:
Wafer Chuck Temperature: 480° C.
Chamber Pressure: 2.5 Torr
Silane flow rate: 180 sccm (standard cubic centimetres per minute)
NH3 flow rate: 2.8 slm
N2 flow rate: 2.5 slm
RF Power: 105 W
Deposition Time: 21 s

Before etching the oxide layer as described below in relation to the particular examples, the nitride layer was removed under the following conditions:
Chamber Temperature: 60° C.
Wafer Chuck Temperature: 60° C.
Chamber Pressure: 10 mTorr
Coil RF Power: 800 W
Bias Voltage: 20V O2 flow rate: 60 sccm
CF4 flow rate: 100 sccm
CH2F2 flow rate: 40 sccm
He flow rate: 8 sccm
Etch Time: 45 s

### Example 1

The transistor of Example 1 is shown in FIG. 4. The transistor was manufactured from C065 flow. This particular transistor is part of the TEM test structure with varying gate critical dimension (CD). Just before the salicide process (after the etching of the nitride layer), the substrate was etched with a solution of hydrofluoric acid. The dimensions of the formed transistor are:
Poly CD: 100 nm
Poly Thickness: 100 nm
Liner Thickness: 8 nm
Recessed Spacer Etch
NiSi Thickness: 13 nm
Nitride passivation/Etch Stop Layer (ESL): 30 nm

### Example 2

The transistor of Example 1 is shown in FIG. 7. The transistor was manufactured from a C065 flow. This particular transistor is part of the TEM test structure with varying gate CD. Just before the salicide process (after the etching of the nitride layer), the substrate was etched with a remote plasma formed from a gas mixture comprising NF₃ and NH₃. The dimensions of the formed transistor are:
Poly CD: 130 nm
Poly Thickness: 100 nm
Liner Thickness: 8 nm
Recessed Spacer Etch
NiSi Thickness: 13 nm
Nitride passivation/ESL: 30 nm

### Example 3 and 4

The transistor of Examples 3 and 4 are shown in FIGS. 9 and 10. The transistors were manufactured from a C065 flow. This particular transistor is part of the TEM test structure with varying gate CD. For example 3, the substrate was etched just before the salicide process (after the etching of the nitride layer) with a remote plasma formed from a gas mixture comprising NF₃ and NH₃. For example 4, the substrate was etched just before the salicide process (after the etching of the nitride layer) with a remote plasma formed from a gas mixture comprising NF₃ and NH₃. The dimensions of the formed transistors are both:
Poly CD: 50 nm
Poly Thickness: 100 nm
Liner Thickness: 8 nm
Recessed Spacer Etch
NiSi Thickness: 13 nm
Nitride passivation/ESL: 30 nm

1. A method for forming a transistor on a silicon substrate, the method comprising:
providing a substrate comprising a gate electrode with a liner comprising silicon and oxygen, and with a sidewall spacer, and source and/or drain region(s) in the substrate adjacent to the gate electrode, a layer at least 5 nm thick comprising silicon dioxide covering at least the source and/or drain regions;
etching the layer comprising silicon and oxygen from at least the source and/or drain regions; and
forming contacts for the source and/or drain region(s),
wherein etching the layer comprising silicon and oxygen is etched from the substrate by steps comprising comprises:
forming an etchant from a plasma formed from a mixture comprising nitrogen trifluoride and ammonia;
exposing the substrate to the etchant; and
annealing the substrate.

2. The method according to claim 1, wherein the source and/or drain contacts are formed by:
depositing a metal or metal alloy layer over the source and/or drain regions; and
annealing the substrate to form metal silicide source and/or drain contacts.

3. The method according to claim 1, wherein the source and/or drain contacts are formed from silicon, nickel, and optionally platinum.

4. The method according to claim 1, wherein etching the layer comprising silicon and oxygen comprises:
exposing the substrate to an etchant formed from a plasma formed from a mixture comprising nitrogen trifluoride and ammonia, and annealing the substrate;
followed by exposing the substrate again to an etchant formed from a plasma formed from a mixture comprising nitrogen trifluoride and ammonia, and annealing the substrate.

5. The method according to claim 1, wherein etching the layer comprising silicon and oxygen comprises:
etching the substrate with a hydrogen fluoride solution;
forming an etchant formed from a mixture comprising nitrogen trifluoride and ammonia; and
exposing the substrate to the etchant.

6. The method according to claim 5, wherein the etching with a hydrogen fluoride solution is carried out before exposing the substrate to an etchant formed from a gas mixture comprising nitrogen trifluoride and ammonia.

7. The method according to claim 1, wherein the layer comprising silicon and oxygen is less than 300 nm in thickness.

8. The method according to claim 1, wherein the plasma is formed at a power density of between 10 and 1000 mW/cm3.

9. The method according to claim 1, wherein the layer comprising silicon and oxygen is covered by a second layer comprising a nitride of silicon.

10. The method according to claim 9, wherein the layer comprising a nitride of silicon is from 5 to 50 nm in thickness.

11. The method according to claim 1, wherein the layer comprising silicon and oxygen is formed as a blanket layer over the surface of the substrate.

12. The method according to claim 11, wherein a layer that is stable to the conditions in the etching steps is formed over part of the blanket layer.

13. The method according to claim 1, wherein the layer comprising silicon and oxygen comprises an oxide of silicon, for example silicon dioxide.

14. The use of an etchant formed from a plasma formed from a mixture comprising nitrogen trifluoride and ammonia in the prevention of undercutting of a sidewall spacer in etching of a layer comprising silicon and oxygen in the manufacture of a semiconductor device.

15. (canceled)

16. The method according to claim 2, wherein the source and/or drain contacts are formed from silicon, nickel, and optionally platinum.

17. The method according to claim 2, wherein etching the layer comprising silicon and oxygen comprises:
exposing the substrate to an etchant formed from a plasma formed from a mixture comprising nitrogen trifluoride and ammonia, and annealing the substrate;
followed by exposing the substrate again to an etchant formed from a plasma formed from a mixture comprising nitrogen trifluoride.

18. The method according to claim 3, wherein etching the layer comprising silicon and oxygen, comprises:
exposing the substrate to an etchant formed from a plasma formed from a mixture comprising nitrogen trifluoride and ammonia, and annealing the substrate;
followed by exposing the substrate again to an etchant formed from a plasma formed from a mixture comprising nitrogen trifluoride.

19. The method according to claim 2, wherein etching the layer comprising silicon and oxygen comprises:
etching the substrate with a hydrogen fluoride solution;
forming an etchant formed from a mixture comprising nitrogen trifluoride and ammonia; and
exposing the substrate to the etchant.

20. The method according to claim 3, wherein etching the layer comprising silicon and oxygen comprises:
etching the substrate with a hydrogen fluoride solution;
forming an etchant formed from a mixture comprising nitrogen trifluoride and ammonia; and
exposing the substrate to the etchant.

21. The method according to claim 2, wherein the layer comprising silicon and oxygen is less than 300 nm in thickness.
